(19) United States
(12) Patent Application Publication
(10) Pub. No.: US 2008/0204040 A1
(43) Pub. Date: Aug. 28, 2008

(54) Systems and arrangements for determining properties of a transmission path

(76) Inventor: Harry Muljono, San Ramon, CA (US)

Correspondence Address: SCHUBERT, OSTERRIEDER & NICKELSON, PLLC;c/o Intellevate, LLC, P.O. BOX 52050, MINNEAPOLIS, MN, 55402, US

(21) Appl. No.: 11/711,987

(22) Filed: Feb. 28, 2007

(51) Int. Cl. G01R 27/02

(52) U.S. Cl. 324/606; 324/713

(57) ABSTRACT

One disclosed method is to automate testing for transmission path impedance conditions on a circuit board. The method can include transmitting a plurality of electrical pulses on a transmission path utilizing an on-board transmitter, the electrical pulses can have a time period and the transmission path can have impedance mismatches to reflect energy of the electrical pulse back towards the on-board transmitter. After the pulse is transmitted, a voltage of the reflected energy can be compared with a reference voltage at different time intervals. A single bit can be acquired for each voltage/time sample and the bits can be sequentially stored in a shift register. The digital data that is stored in the shift register can be compared to existing data in memory to determine a quality of the transmission path of the printed circuit board.

### FIELD OF THE DISCLOSURE

The present disclosure is related to the field of electronics and more particularly to the field of transmission path characteristics.

### BACKGROUND

Physical conductors for conveying digital data, such as copper traces of a circuit board are commonly utilized as a transmission path for high-speed serial communication between integrated circuits or from “chip-to-chip” on a circuit board. A typical system can have transmitters placed within an integrated circuit that send data over the transmission paths that a receiver on another integrated circuit. The transmission paths can include components such as conductors, pads, “vias,” traces, strip lines, devices and even wires where each component can have a different impedance. A circuit board will typically be designed with components that have a consistent impedance, however production tolerances and device tolerances can add up such that the impedance of the transmission path does not meet the required specification. In this case the circuit board will under perform at the desirer speeds. For example, when such an impedance matching problem occurs on a transmission path, the transmitter may not be able to reliably transit data at the required speeds.

When a transmission path changes in direction, changes in dimensions, changes in intrinsic impedance, changes in composition and has other changes, part of an incident wave or transmitted wave will reflect off of such changes and will typically be reflected back towards the transmitter. Generally, a reflection of an electromagnetic wave can be thought of as an “echo” where a wave, which has been generated, is reflected at one or more points along the transmission medium. Different points or locations along the transmission line will typically reflect different magnitudes of energy.

Traditionally, if significant errors occur in on-board communications, manual testing is conducted to determine if unacceptable impedance mismatches are present on the transmission lines. Such manual testing is expensive and traditional test methods have several drawbacks. For example, to achieve acceptable results, the circuit board under test should be disconnected from the coupled components to isolate the transmission path to be tested such that the reflection readings are not skewed by the coupled devices. To achieve an acceptable measurement, time domain reflectometry equipment (TDR) equipment is commonly utilized. Such equipment is relatively expensive, must be operated by a trained technician and must be regularly calibrated. Further, the rise time of the incident waveform that is generated by a TDR device does not necessary have the same characteristics as the actual signals that utilize the transmission line. This also leads to inaccurate readings.

### BRIEF DESCRIPTION OF THE DRAWINGS

Aspects of the disclosure will become apparent upon reading the following detailed description and upon reference to the accompanying drawings in which, like references may indicate similar elements:

FIG. 1 depicts a block diagram of a transmission path testing system;

FIG. 2 is a graphic depicting reflected energy on a transmission path; and

FIG. 3 illustrates a flow diagram of a method for testing circuit boards.

### DETAILED DESCRIPTION OF EMBODIMENTS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

While specific embodiments will be described below with reference to particular configurations of hardware and/or software, those of skill in the art will realize that embodiments of the present disclosure may advantageously be implemented with other equivalent hardware and/or software systems. Aspects of the disclosure described herein may be stored or distributed on computer-readable media, including magnetic and optically readable and removable computer disks, as well as distributed electronically over the Internet or over other networks, including wireless networks. Data structures and transmission of data (including wireless transmission) particular to aspects of the disclosure are also encompassed within the scope of the disclosure.

In one embodiment, the method can include transmitting electrical energy on a transmission path and detecting resulting energy on the transmission line utilizing a comparator driven by a voltage stepper module. The comparator can compare a reflected wave or an incident wave to the reference voltage utilizing a predetermined time-voltage sequencing after each pulse is transmitted. The comparator output data can be stored sequentially utilizing a flip flop and a shift register. The reflected voltage measurements during the multiple time samples can provide a profile indicative of parameters of the transmission path including an anticipated performance that can be provided by the transmission path.

The magnitude of the conductance and impedance mismatches at various locations on the transmission path can be measured by the system and the physical location of mismatch can also be determined based on the equation velocity=distance×time, where the velocity of the pulse is known and the time the pulse is sent and the time the reflection is received can be determined. Thus, the location on the transmission path of a discontinuity and the magnitude of the discontinuity can be determined. The disclosed arrangement can be built into a single integrated circuit and can function as an automated self-test for the circuit board. Thus, this “on-board” automated self test system can be activated during a “power-up” or initialization and board performance can be automatically predicted by the disclosed arrangements. Accordingly faulty circuit boards can be identified at an early stage of manufacturing without the need for manual testing. The arrangements generally can eliminate the need for expensive test equipment and expensive manual labor.

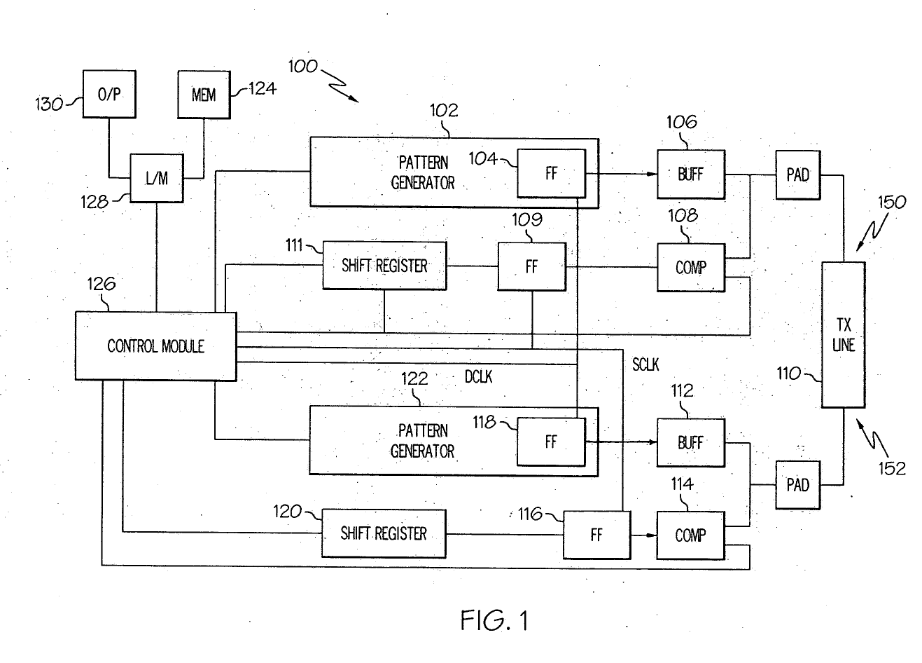

Referring to FIG. 1 an on-board transmission path tester apparatus 100 that can perform an automated self-test is disclosed. The transmission line 110 can have a transceiver unit connected to a first end 150, and a transceiver unit connected to a second end 152. The transceiver unit connected to the first end 150 can include a pattern generator 102, a flip-flop 104 to clock data out of the pattern generator 102, and a transmitter/buffer 106 to provide a voltage pulse on the transmission line 110. The transmitted wave can be reflected off of impedance mismatches such as those caused by the interconnection between the buffer 106 and the connection point on the circuit board, the interface between the connection point and the transmission line 110 and so on.

In one embodiment, a transmitter such as the buffer 106 under the control of pattern generator 102 both mounted on the same integrated circuit can transmit a plurality of electrical pulses on transmission path 110. The electrical pulses can have a time period and the transmission path 110 can have impedance mismatches to reflect energy back towards the transmit buffer 106. The comparator 108 on the integrated circuit can be utilized to compare voltages resulting from the transmitted pulses to a plurality of reference voltages utilizing a time-voltage sampling sequence as controlled by logic module/control module 126.

In the sampling/comparing process the comparator 108 can produce a bit of digital data during each compare or for each sampling point and the digital data can be stored sequentially in the shift register 111 to provide a profile of impedances discontinuities present on the transmission path 110. The digital data can be compared to digital data stored in the memory 124 where the memory can store predetermined performance metrics and the digital data from this compare process can indicate if a circuit board has acceptable performance parameters and will pass a predetermined test procedure. In addition, an alarm can be set or stored in memory 124 when the transmission line 110 on the circuit board does not pass a predetermined transmission path test parameter.

In one embodiment, a clock signal from the control module 126 can be utilized to control the time-voltage sampling of the reflected energy by providing stepped voltages to the comparator 108, and 114, by clocking flip-flops such as flip-flop 109 and shift register 111 such that bits of data can be stored sequentially after each time voltage compare. The plurality of electrical pulses and clocking system can have a pre-determined timing pattern based on characteristics of the transmission path, such that the test data can focus gathering data on locations of the transmission path 110 that have inherent discontinuities or a high likelihood of problems. The sampling of the reflected energy can be achieved during a time period after the transmitted energy travels from the buffer transmitter 106 to a known location in the transmission path 110, and back to the sensing locations (i.e. the comparators 108 and 114).

The control module 126 can generate a time synchronized waveform to provide varying voltages to an input of the comparator 108 and the comparator 108 can compare the waveform with the reflection voltage during the appropriate time period. Thus, the varying voltage can be compared with the reflected voltage utilizing clock signals to synchronize the voltage reference signal, and comparator flip flops, and shift register timing. In one embodiment, the varying voltage can be implemented as a voltage stepped waveform.

The pattern generator 102 and transmit buffer 106 of the automated testing system can transmit one electrical pulse on the transmission path 110 for a predetermined time interval, and a detector/comparator such as 108 and 114 can detect a voltage on the transmission path resulting from a reflection of the pulse and end to end conduction of the pulse a predetermined time after an initial portion of the pulse is transmitted. The apparatus can also include a clocked storage module such as the shift registers 111 and 120 to store indications of the detected voltage, and a logic module portion of the control module 126 to determine if the transmission path 110, based on the test results, meets one of many predetermined criteria. The apparatus 100 can also include a combinational logic module in the control module 126 to compare the indications of the detected voltage at the output of the comparators 108 and 114 to the predetermined criteria stored by memory 124. A data clock and a sampling clock can be included in the control module 126 wherein the data clock can be synchronized with the sampling clock.

The apparatus 100 can determine impedance abnormalities and possibly impedance mismatches in a transmission path 110 where all illustrated components except for the transmission path 110 can be collocated on an integrated circuit where the transmission path can be located on a printed circuit board.

The apparatus 100 can utilize time domain reflectometry (TDR) to acquire data about impedance mismatches on a transmission path 110. In one embodiment, the pattern generator 102 can generate a predetermined pattern that is customized for a specific transmission path 110 where the transmission path has predetermined physical attributes or known impedance discontinuities at particular physical locations. Thus, the time when, and voltage level where, the samples are taken for a reflection can be concentrated such that a particular “problem” location becomes a focus of the testing.

In one embodiment the transmission path 110 can be test path that loops out from and back to the same integrated circuit or where both ends of the transmission path terminate at a single integrated circuit. This embodiment can make the assumption that the results of the tested transmission path 110 represents the performance of other traces on the circuit board based on a homogeneous fabrication process. Measuring the pulse or the voltage or portion of voltage conducted from buffer 106 to comparator 114 can provide a conductance parameter of the transmission path 110.

After transmission of an electrical pulse by buffer 106, a portion of the pulse may be reflected off of impedance mismatches, sending a much smaller pulse (typically less that a fourth of the transmit energy) back to the input of comparator 108. A Vref signal can be provided to a second input of the comparator 108 by a control module 126 at predetermined time intervals and the output of the comparator 108 can be clocked into the flip flop 109. When the flip-flop 109 is clocked by clock signal it can sample or acquire a logic one or a logic zero at the output of the comparator 108 and provide a series or sequence of binary data stagger in time to the register 111. As the register 111 is clocked by the control module 126, the register 111 can sequentially accept bits acquired by the flip-flop 109.

The transceiver unit connected to the second end 152 can include a pattern generator 122 a flip-flop 118 to clock data out of the pattern generator 122, and a transmission buffer 112 to provide the signal transmitted over the transmission line 110. The transceiver unit connected to the second end 152 can also have a comparator 114 connected to a flip-flop 116. After transmission of an electrical pulse by buffer 112, a portion of the pulse may be reflected off of impedance mismatches sending a much smaller pulse back to the input of comparator 114. A Vref signal can be provided to the comparator 114 by the control module 126 at predetermined time intervals and the output of the comparator 114 can be clocked into the flip flop 116. The flip-flop 116 can sample the output of the comparator 114 and provide a series or sequence of binary data stagger in time to the register 120. Thus, the registers 111 and 120 can store data bits that are binary samples of reflected voltages for different reflection voltages at different time intervals.

Memory 124 can store binary sequences that can be compared to the binary sequences stored by the registers 111 and 120. The data contained in the registers 111 and 120 can be compared to predetermined data stored by memory 124 utilizing compare module 128. The compare module 128 can determine if the transmission path 110 between the transmission buffer 106 and the transmission buffer 112 meets the predetermined criteria by comparing the criteria stored in memory 124 with the tests results stored in the registers 111 and 120. Generally, results of such a test can be utilized as a quality control feature for the circuit board after it is manufactured. In other embodiment, the system 100 can be utilized during operation and in other embodiments when the circuit board has a know failure. Thus, if successful testing results are acquired, it can be assumed that the tested transmission path on the circuit board will perform satisfactorily during high speed data transmissions.

Alternately described, the system can be viewed as an alternating current input output loop back (ACIOLB) circuit. Such circuits can be utilized as part of the input/output circuitry of integrated circuit. Such circuitry can also be utilized to test timing of signals. As stated above generally, a pre-programmed pattern from pattern generator 102 can be driven onto the transmission line 110. The pattern can have a known voltage swing and the comparator 108 can be activated to capture the reflected waveform at a particular time. In one embodiment, the rising edge of the sampling clock can acquired the value at the output of the comparator 108. The “transmit and capture” process can be done multiple times, each time with a different reference voltage level (i.e. Vref level) and at a different time after the initial portion of the transmission is made.

In one embodiment, Vref can be stepped after each transmitted pulse in increments of thirty (30) millivolt, from thirty (30) millivolts to three hundred (300) millivolts. Hence, the reflected voltage can be tested from thirty (30) millivolts to three hundred (300) millivolts, where reflections in excess of three hundred 300 millivolts would be typically be considered an unacceptable value and this could be determined by the baseline data stored by memory 124. Vref could be provided as a step voltage function having the same frequency as the transmitted pattern.

After an acceptable sample is obtained or all desired Vref levels are tested at a particular time delay, the capture clock can be time-shifted (delayed) with respect to output clock and the same “stepped voltage” process can be commenced. After the desired time and voltage test points are acquired, the profile of the reflected waveform can be obtained as a series of bits that can be interpreted to provide a profile of the transmission path. With further processing by the control module 126, a reflection coefficient such as “S” parameters can be determined.

In one embodiment, “S” parameters can be acquired by comparing the magnitude of reflected and incident waveforms utilizing time synchronized/concurrent data from both registers 111 and 120 to see how much energy made it through the transmission path 110 versus how much was reflected. To acquire the S parameters, the buffer 106 can send a signal over a trace on a printed circuit board (i.e. transmission line 110) and detect the magnitude and time delay of the maximum reflected energy. The maximum reflected energy can then be compared with the incident signal on the receiving or other end of the transmission line 152 by comparator 114. This metric can also determine that power “loss” created by the transmission path 110. This metric can be utilized to determine if the circuit board will meet performance standards during system operation.

The apparatus 100 offers several advantages over traditional transmission path testing methods. The disclosed apparatus can make an actual measurement of impedance discontinuities utilizing circuitry that is “on-board” and connected directly to the transmission path 110, rather than relying on external testing equipment that can introduce errors in a number of ways. As stated above, such external equipment can often yield inaccurate and artificial test results. The teachings of the present disclosure also allow a large number of interconnect properties to be determined simultaneously. Further, the location of the impedance discontinuity all along the transmission path of an interconnection can be easily determined using a time analysis.

Although only one transmission path is illustrated, the transmission line 110 could be a differential data line. The transmission line 110, termination components and supporting components can be designed to provide a fifty (50) Ohms impedance to the incident pulse. The buffer 106, can also have an output impedance of fifty (50) Ohms such that the apparatus 100 has impedance matched components. The comparator 108 can have a very high input impedance on the order of Mega ohms such that it's impedance has a minimal affect on the transmission path impedance.

In one embodiment, memory 124 can store a series of binary sequences and based on multiple compares with the contents of the registers 111 and 120, a quality level of the transmission path 110 can be determined. The results of one transmission path can be an indicator of other transmission paths on the circuit board based on production tolerances. Thus, circuit boards can self-automate a “self-test” procedure on specific transmission paths and based on the results of testing such a transmission path the circuit board can assign and store a grade, a rank. A rating or a performance level such that the manufacturer can assign higher speeds to boards having the best grade. Thus, boards with exceptional test results can be utilized at the highest data speeds while a board that has deficiencies in the transmission path can be configured to run at lower data speeds. When a circuit board is deemed to have poor transmission path qualities it can be scrapped. Such a system can provide quality control on circuit boards without requiring individual testing of circuit boards by a technician.

Output port 130 can provide a visual alarm or multiple status indicators by lighting one or more light emitting diode to indicate whether the transmission path passes the test. In addition the output port can provide a connector where the status stored on the board can be downloaded where a testing system can read and store a circuit board identifier and the results of the self test. In another embodiment, the output port 130 can be a connector that can interface with test equipment such that an identification number of the board and the performance of the board can be electronically recorded.

The self test system can be strategically placed on selected “problem” traces or transmission paths. In a circuit board design some traces are more susceptible to having poor performance due to their location or other factors or are critical to system operation. The apparatus could be utilized on a single trace that is the most likely to have problems and if the transmission path checks out as acceptable, then it can be assumed that all traces on the circuit board are acceptable. In another embodiment, all of the traces of a high speed data bus can utilize the disclosed system and every “speed critical” trace can be tested. In yet another embodiment, a single impedance testing system can be utilized and the system can be multiplexed in to every critical transmission line such that the system 100 can check a first transmission path then test a second transmission path, and so on until all transmission paths are tested with a single system 100.

The transmitted electrical energy can be a series of 1.2 volt pulses with a predetermined pulse duration configured such that all of the reflected energy returns prior to the next energy pulse being transmitted. In this embodiment, a reflection voltage that creates a voltage on the transmission line from zero volts to as much as 300 millivolts can be anticipated. Pulses of varying voltages and time durations can be transmitted and frequency responses for such variations could be identified without parting from the scope of the present disclosure. In addition, a distance between the transmitter and the impedance mismatches can be determined by acquiring different time amplitude samples of the reflected wave utilizing known locations of transmission medium changes and information about the propagation velocity of the energy within the transmission path.

In another embodiment, a high-speed serial link designed to carry data at high speeds can be automatically tested during a qualification process by collecting data obtained from the on board time-domain-reflectometry (TDR) self test apparatus 100. In accordance with the present disclosure, the disclosed arrangements can perform as a “mini network analyzer” and can determine the attributes of a mismatch on a transmission path utilizing TDR. The traditional manual process for gathering such data on production circuits is a very expensive and unreliable and the systems and methods of the present disclosure can eliminate such a process.

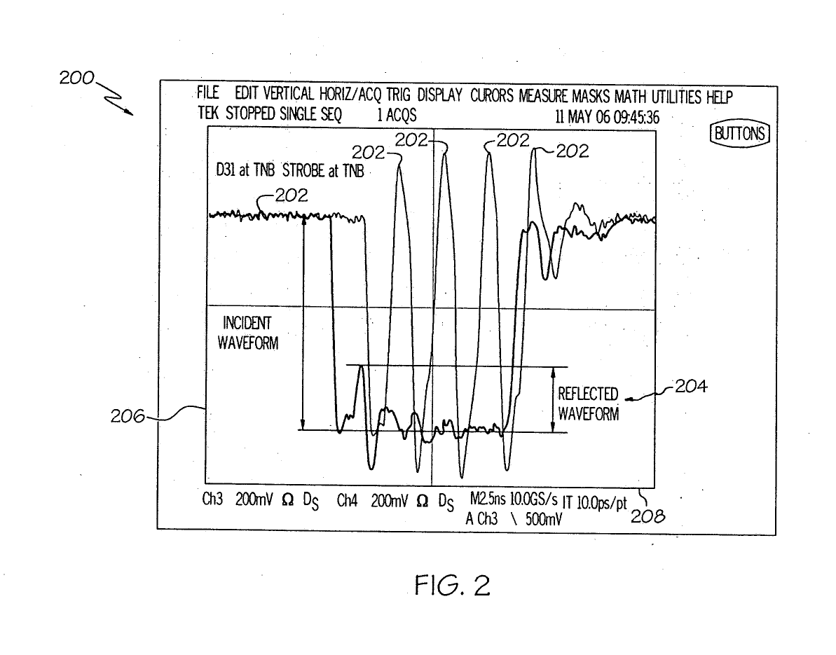

Referring to FIG. 2, a graphical representation 200 of an incident pulses or waveforms 202 and a reflected waveforms 204 are depicted. The vertical axis 206 provides voltage increments and the horizontal axis 208 provides time increments. In response to a transmitted pulse 202 on the transmission path, the middle of the graph on the horizontal axis provides a progression of time where the pulse has been removed from the transmission path and reflected energy is returning to the transmit location. The reflected waveform can be measured as a positive voltage transition that occurs after completion of the transmitted pulse. Accordingly, impedance mismatches that are causing such positive voltage transitions can be measured utilizing a comparator and various reference voltages at various times as described above with reference to FIG. 1

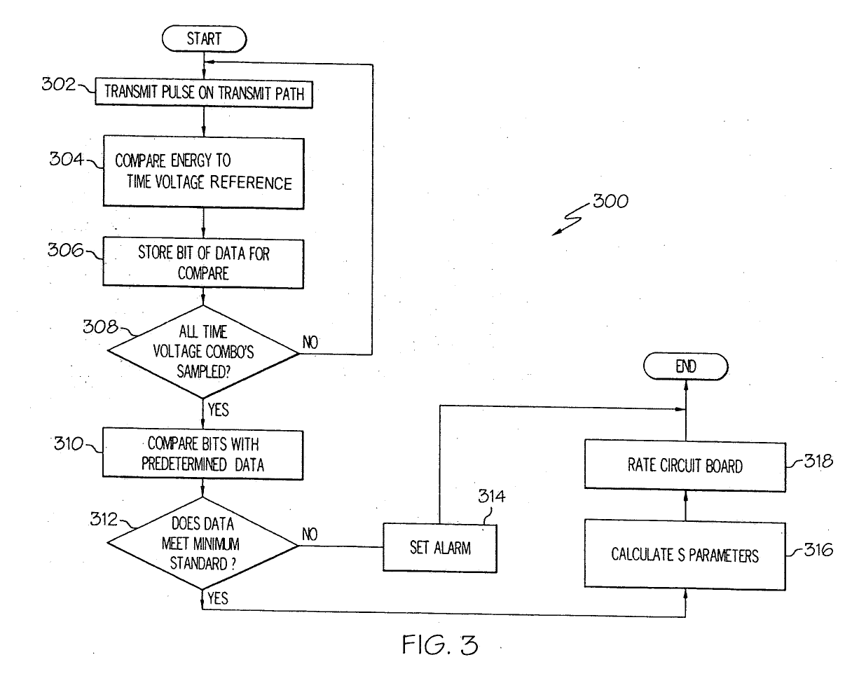

Referring to FIG. 3, a method for automated testing of the characteristics of a transmission path on a circuit board is disclosed. As illustrated by block 302, a single pulse can be transmitted on a transmission path and it is likely that a portion of the transmitted pulse will be reflected back to the transmitter/source and a portion will traverse the transmission line. The reflection can cause electrical energy in the form of a measurable voltage to be returned to the transmitter and the amount of the reflection can be measured as a voltage. As illustrated by block 304, the voltage level of the reflected energy can fed to the input of a comparator where the voltage level can be compared a reference voltage. Additionally, the voltage level of the conducted energy can be detected by the system.

The output of the comparators can be a binary signal indicating if the reflected voltage rises and the conducted voltage rises to the level of the reference voltage for each pulse. Thus, the reference voltage can be a voltage step function that steps to a higher voltage after each pulse generated by the pattern generator. Therefore, each bit that can be stored will indicate if the reflected voltage and/or the conducted voltage is above a specific level. In other embodiments, it can be determined if the reflected voltage is below a specific level. The compare process could also be performed at multiple times after a single pulse if the transmission line is long enough and the sampling components can operate fast enough to acquire the data.

The time when the sample is taken can be controlled by a clock signal provided to a flip flop that is connected to the output of the comparator such that the flip-flop accepts and stores the comparator signal at the appropriate time. Since the distance from the transmit buffer to transmission line irregularities can be calculated, the clock signal provided to the flip flop can be timed such that the system can sample the locations in the transmission line with a high likelihood of having an “out of spec” impedance mismatch. Accordingly, such time delays can focus the sample such that it detects the most problematic areas. In other embodiments, the entire transmission path can be checked.

The digital data or bits resulting from the test procedure can be stored for the compare, as illustrated in block 306. At decision block 308, it can be determined if all the desired time voltage combinations have been checked. If all time voltage combinations have not been acquired, the process can revert back to block 202 and if they have been acquired, the process can proceed to block 310. As illustrated in block 310, the set of digital data representing the profile of the transmission path can be compared to a predetermined set of stored digital data. As illustrated in decision block 312, it can be determined as a result of the compare process if the transmission path meets predetermined criteria. If the criterion is not met, then an alarm can be set as illustrated in block 314. If the predetermined criterion is met, then S parameters can be determined as illustrated in block 316. As illustrated by block 318, the circuit board performance can be predicted and the circuit board can be ranked or rated. Such a rank rating can predict what level of performance (for example clock speeds) that the circuit board should be able to operate at without significant errors. The process can end thereafter.

The method described can test for transmission line performance parameters that are consistent with Gigahertz digital data transmissions. Such a testing process can be done automatically without human intervention as part of an on-board start up test procedure. This feature can identify deficient circuit boards and without the requirement of manually testing on the production floor.

Each process disclosed herein can be implemented with a software program. The software programs described herein may be operated on any type of computer, such as personal computer, server, etc. Any programs may be contained on a variety of signal-bearing media. Illustrative signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet, intranet or other networks. Such signal-bearing media, when carrying computer-readable instructions that direct the functions of the present disclosure, represent embodiments of the present disclosure.

The disclosed embodiments can take the form of an entirely hardware embodiment, an entirely software embodiment or an embodiment containing both hardware and software elements. In a preferred embodiment, the disclosure is implemented in software, which includes but is not limited to firmware, resident software, microcode, etc. Furthermore, the disclosure arrangements can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The control module can retrieve instructions from an electronic storage medium. The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD. A data processing system suitable for storing and/or executing program code can include at least one processor, logic, or a state machine coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

It will be apparent to those skilled in the art having the benefit of this disclosure that the present disclosure contemplates methods, systems, and media that can automatically tune a transmission line. It is understood that the form of the shown and described in the detailed description and the drawings are to be taken merely as examples. It is intended that the following claims be interpreted broadly to embrace all the variations of the example embodiments disclosed.

What is claimed is:

1. A method comprising:
transmitting electrical pulses onto a first end of a transmission path on a circuit board utilizing a transmitter on an integrated circuit, the transmission path to conduct a portion of energy of the electrical pulses to a second end of the transmission path, the transmission path having impedance mismatches that reflect a portion of the energy from the electrical pulses back towards the first end of the transmission path;
comparing voltages on the transmission path resulting from the transmitted electrical pulses to a plurality of reference voltages at a plurality of times to produce digital data representative of a parameter of the transmission path using a compare module on the integrated circuit;
storing the digital data on the integrated circuit; and
comparing the digital data to predetermined performance metric on the integrated circuit.

2. The method of claim 1, wherein the parameter comprises a reflection parameter.

3. The method of claim 1, wherein the parameter comprises a conductance parameter.

4. The method of claim 1, further comprising setting an alarm in response to the digital data indicating that the parameter does not meet the predetermined performance metric.

5. The method of claim 1, further comprising recording an identification of the circuit board and a performance parameter of the circuit board.

6. The method of claim 1, wherein the electrical pulses, the reference voltages and a sampling time occur in a pre-determined automated pattern.

7. The method of claim 1, further comprising sampling the reflected energy during a time period in which energy from a pulse from the transmitted pulses can travel from the transmitter to a known transmission path location and back to the compare module.

8. The method of claim 1, wherein a timing of the comparing is achieved based on physical features of the transmission path.

9. The method of claim 1, wherein comparing comprises generating a time synchronized step waveform reference voltage with predetermined pulse widths.

10. An apparatus comprising:
a transmitter to transmit at least one electrical pulse on a transmission path;
a detector coupled to the transmission path to detect a voltage on the transmission path resulting from the transmitted electrical pulse;
a clocked storage module to store an output of the detector indicating a magnitude of the detected voltage; and
a logic module to determine if the transmission path meets a predetermined criterion based on the output of the detector.

11. The apparatus of claim 10, wherein the logic module comprises combinational logic to compare the indication to the predetermined criterion.

12. The apparatus of claim 10, further comprising a data clock and a sampling clock wherein the data clock is synchronized with the sampling clock.

13. The apparatus of claim 10, wherein the detected voltage is a reflected voltage.

14. The apparatus of claim 10, wherein the logic module comprises a ranking module to indicate an anticipated performance of the transmission path.

15. The apparatus of claim 10, further comprising an output port to download board performance information.
